(19) United States
(12) Patent Application Publication
(10) Pub. No.: US 2026/0110718 A1
(43) Pub. Date: Apr. 23, 2026

(54) METHOD AND SYSTEM FOR IDENTIFYING WIRING CONFIGURATION AND VOLTAGE RATING OF AN ELECTRICITY METER USING MULTIDIMENSIONAL ANALYSIS

(71) Applicant: Accuenergy (Canada) Inc., Toronto (CA)

(72) Inventors: Yufan Wang, Toronto (CA); Ketao Li, Toronto (CA); Liang Wang, Toronto (CA)

(73) Assignee: Accuenergy (Canada) Inc., Toronto (CA)

(21) Appl. No.: 18/920,898

(22) Filed: Oct. 20, 2024

(51) Int. Cl. G01R 22/06

(52) U.S. Cl. CPC G01R 22/068

(57) ABSTRACT

The present invention relates to a method and system for identifying the wiring configuration and voltage rating of an electricity meter. The method involves measuring various voltage values, including phase and line voltages, relative to a virtual neutral point. A controller calculates effective values and phase angles from the measured voltages and performs a multidimensional analysis, including voltage ratio analysis, phase angle analysis, and zero-sequence voltage analysis, to determine the wiring configuration, such as a three-phase three-wire or three-phase four-wire configuration. The method also incorporates a voltage spectrum analysis, utilizing a Fast Fourier Transform (FFT), to determine the voltage rating. Multiple iterations of the identification process are performed to confirm the accuracy of the results. The system includes a voltage measurement unit, a processor, and a memory for executing the method. The invention improves reliability in wiring configuration identification and enables anomaly detection.

### FIELD OF THE INVENTION

The present disclosure relates to methods and systems for automatically identifying wiring configurations and voltage ratings in electricity meters, particularly in three-phase electrical systems.

### BACKGROUND

In the field of electricity metering, accurate measurement of energy usage is highly dependent on the correct identification of the wiring configuration and voltage rating of the electrical system to which the meter is connected. The wiring configuration, such as whether the system is a three-phase three-wire or three-phase four-wire configuration, and the voltage rating directly influence how the meter interprets voltage and current measurements. Incorrect configuration can result in inaccurate energy readings, leading to faulty billing or incorrect data for monitoring purposes.

Traditionally, these configurations are manually set by electricians during the installation process. This manual configuration approach is prone to human error, particularly in complex electrical systems, where small mistakes can lead to significant inaccuracies in energy measurement. Additionally, manual configuration lacks adaptability, requiring specialized knowledge and tools to ensure that the meter is properly set up, which can further complicate installation and maintenance processes.

Given the increasing complexity of modern electrical grids, there is a need for an automated method that can accurately identify both the wiring configuration and the voltage rating of an electrical system without relying on manual input.

### SUMMARY OF THE INVENTION

The present invention provides a method and system for automatically identifying the wiring configuration and voltage rating of an electricity meter, particularly in three-phase electrical systems. The method includes measuring a plurality of voltage values, including phase voltages relative to a virtual neutral point and line voltages. The controller within the electricity meter calculates effective values and phase angles for the measured voltage values and performs a multidimensional analysis that includes voltage ratio analysis, phase angle analysis, and zero-sequence voltage analysis.

The method determines the wiring configuration of the electricity meter based on the results of this multidimensional analysis, Specifically, a three-phase three-wire configuration is identified when the absolute value of the zero-sequence voltage is below a first threshold, and certain ratios and phase angle differences fall within predefined ranges. A three-phase four-wire configuration is identified when the zero-sequence voltage exceeds a second threshold, and different ratios and phase angle differences are met.

The method further includes performing a voltage spectrum analysis using Fast Fourier Transform (FFT) to determine the voltage rating of the electricity meter. Additional steps may include collecting voltage data over a predetermined period and calculating statistical parameters, such as the mean, standard deviation, and 95% confidence interval for the fundamental frequency amplitudes. The voltage rating is determined by comparing these statistical parameters to predefined voltage rating ranges.

To enhance accuracy and reliability, the system confirms the determined wiring configuration and voltage rating by performing the identification process through multiple iterations. If the results remain consistent across the iterations, they are confirmed; if inconsistencies arise, an uncertainty is reported. The method can further adapt the threshold values used in the multidimensional analysis based on historical data to improve its adaptability to different power grid environments.

Additionally, the system is capable of detecting anomalies in the measured voltage values, such as voltage sags, surges, or imbalances, and generating alerts when such anomalies are detected, allowing for prompt corrective action.

The invention also includes a system that consists of a voltage measurement unit, a processor, and a memory storing instructions that cause the system to perform the described method. Furthermore, the invention provides a non-transitory computer-readable storage medium containing instructions that, when executed by a processor, enable the electricity meter to perform the described method. This comprehensive solution offers automatic, reliable identification of wiring configurations and voltage ratings, ensuring enhanced accuracy in various electrical environments.

### BRIEF DESCRIPTION OF THE DRAWINGS

FIG. 1 is a block diagram of an electricity meter designed for monitoring power usage and power quality at any metered point within a power distribution system according to some embodiments of the present invention.

FIG. 2 is a flow chart of a method for identifying a wiring configuration and voltage rating of an electricity meter according to some embodiments of the present invention.

### DETAILED DESCRIPTION

The following description should be read with reference to the drawings, in which like elements in different drawings are numbered in like fashion. The drawings, which are not necessarily to scale, depict selected embodiments and are not intended to limit the scope of the invention. Although examples of construction, dimension, and materials are illustrated for the various elements, those skilled in the art will recognize that many of the examples provided have suitable alternatives that may be utilized.

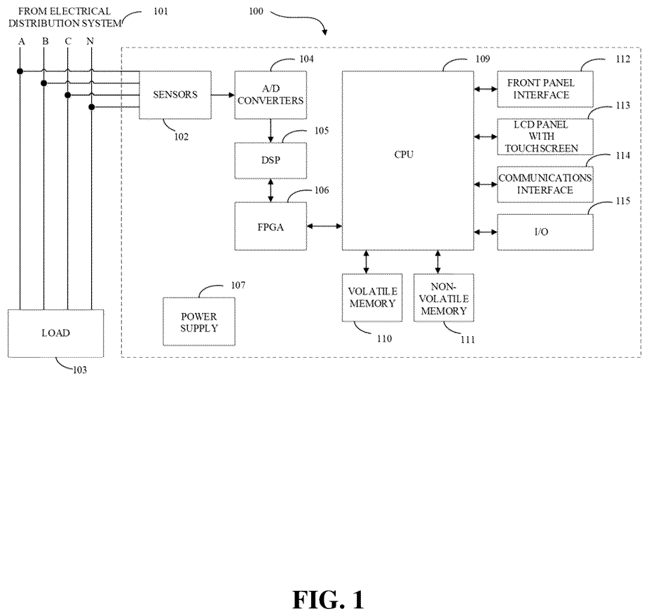

FIG. 1 illustrates a block diagram of an electricity meter 100 designed for monitoring power usage and power quality at any metered point within a power distribution system.

The meter 100, as shown in FIG. 1, is composed of several components, including multiple sensors 102 connected to various phases A, B, C, and N (neutral) of an electrical distribution system 101. It also includes multiple analog-to-digital (A/D) converters 104, a power supply 107, volatile memory 110, non-volatile memory 111, a front panel interface 112, and a processing module containing at least one Central Processing Unit (CPU) and/or one or more Digital Signal Processors (DSP), such as DSP 105 and CPU 109. Additionally, the meter 100 comprises a Field Programmable Gate Array (FPGA) 106, which functions as a communication bridge, facilitating data transfer between various processors (105 and 109).

The sensors 102 are tasked with detecting electrical parameters, including voltage and current, on the incoming lines (phase A, phase B, phase C, and neutral N) of an electrical power distribution system 101, which is connected to at least one load 103 consuming the supplied power. In some embodiments, the sensors 102 consist of current transformers and potential transformers, each of which is paired with one phase of the incoming power lines. The primary winding of each transformer is connected to the incoming lines, while the secondary winding outputs a voltage that corresponds to the sensed voltage and current. These outputs are connected to the AD converters 104, which are responsible for converting the analog signals from the transformers into digital signals for processing by the DSP 105.

The A/D converters 104 convert the analog voltage outputs into digital signals, which are then transmitted to a gate array, such as the Field Programmable Gate Array (FPGA) 106. The FPGA 106 relays these digital signals to the CPU 109 for further processing.

The CPU 109 or DSP processors 105 are designed to receive digital signals from the A/D converters 104 and perform necessary computations to evaluate power usage and manage the overall operations of the meter 100. In certain embodiments, the CPU 109 and DSP 105 may be integrated into a single processor to fulfill both roles. Alternatively, other programmable logic devices, such as an Erasable Programmable Logic Device (EPLD) or a Complex Programmable Logic Device (CPLD), may replace the FPGA 106. In some configurations, digital samples output from the A/D converters 104 may be sent directly to the CPU 109, bypassing the DSP 105 and FPGA 106.

The power supply 107 provides power to each component of the meter 100. In one embodiment, the power supply 107 is a transformer with its primary windings connected to the incoming power lines to deliver a nominal voltage at its secondary windings. In another embodiment, an independent power source provides power to the power supply 107.

As depicted in FIG. 1, the front panel interface 112, connected to the CPU 109, includes indicators, switches, and various input options. Additionally, the LCD panel with touchscreen 113, coupled to the CPU 150, facilitates user interaction and the communication of events, such as alarms and instructions. The LCD panel 113 can display information in multiple formats, including alpha-numeric lines, graphics, videos, and animations.

An input/output (IO) interface 115 may be included to handle external inputs to the meter 100 and output data, such as serial data, to other devices. In some examples, the I/O interface 115 may contain a connector for receiving cards or modules that extend or modify the functionality of the meter 100.

The meter 100 also includes volatile memory 110 and non-volatile memory 111. Volatile memory 110 stores sensed and generated data for subsequent processing or display at the meter 100 or a remote location. It consists of internal storage memory, such as Random-Access Memory (RAM). Non-volatile memory 11 stores data using removable memory, such as magnetic storage, optical media (e.g., CDs or DVDs), solid-state storage (e.g., CompactFlash cards, Memory Sticks, SD cards), or any other memory storage technologies, both current and future. This memory is used for recording historical data trends, waveform captures, event logs (with timestamps), and digital samples, which can later be downloaded to a client application, web server, or PC application.

In some embodiments, the meter 100 includes a communication interface 114, or network interface, to enable communication between the meter and external devices, such as a remote terminal unit, programmable logic controller, or computing devices (e.g., desktop computers, laptops). The communication interface 114 could be a modem, Network Interface Card (NIC), wireless transceiver, or another type of interface supporting both wired and wireless connectivity. Wired connections may include cabling (such as RS232, RS485, USB, or Ethernet) and an appropriately configured communication port. Wireless connectivity may utilize protocols such as Bluetooth™, infrared, Wi-Fi (e.g., 802.11.X), or satellite transmission, among others.

The meter 100 may communicate with a server or another computing device through the communication interface 114, potentially connecting to a communication network (e.g., the Internet) via various means, such as dial-up, DSL, satellite, cellular, or wireless transmission. The network may be a Local Area Network (LAN), Wide Area Network (WAN), or any system connecting multiple computers for communication through network messages. The server can communicate using protocols like Transmission Control Protocol/Internet Protocol (TCP/IP), File Transfer Protocol (FTP), Hypertext Transfer Protocol (HTTP), or secure protocols like HTTPS, IPSec, PPTP, or SSL. The server may also store data received from the meter 100 or meter for future retrieval.

In some embodiments, when a power event (such as a voltage surge or current short circuit) occurs, the meter 100 may digitize waveforms, store them, and transmit the data to a central server. The CPU 109 may use these digitized waveforms to compute electrical parameters like harmonics, magnitudes, and phasor analysis.

Additionally, the meter 100 may execute an e-mail client to notify utilities or customers of power quality events, allowing quick response. The meter 100 can automatically update firmware and software by accessing a remote server for program code updates.

The meter 100 may be implemented through hardware, software, firmware, or a combination thereof, with an operating system and application programs managing various processes and functions.

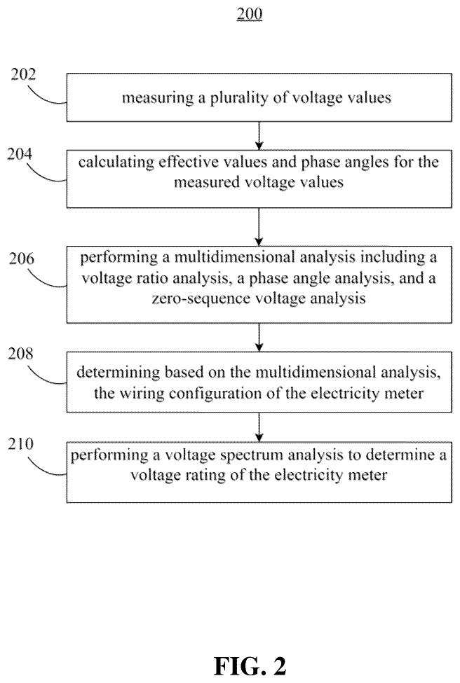

FIG. 2 illustrates a flow chart of a method for identifying a wiring configuration and voltage rating of an electricity meter, executed by the controller of the meter.

The controller of the meter, which encompasses the processing capabilities of the Central Processing Unit (CPU 109), Digital Signal Processor (DSP 105), and other components such as the Field Programmable Gate Array (FPGA 106), is responsible for managing and executing the various computational tasks required for the identification process.

The controller receives inputs from multiple sensors 102, which are attached to the incoming power lines, including phases A, B, C, and neutral (N), and measure electrical parameters such as phase voltages (V_{A}, V_{B}, V_{C}) and line voltages (V_{AB}, V_{BC}, V_{CA}). These analog voltage values are digitized by A/D converters 104 and processed by the controller, with the FPGA 106 facilitating data communication between the processing components.

The controller performs the necessary calculations, including determining effective values, phase angles, voltage ratios, and zero-sequence voltages, to conduct a multidimensional analysis. Based on this analysis, the controller identifies the wiring configuration (three-phase three-wire or three-phase four-wire) of the electricity meter. Additionally, the controller, using the CPU 109 and DSP 105, performs a voltage spectrum analysis (e.g., Fast Fourier Transform) to determine the system's voltage rating.

Memory components, including volatile memory 110 and non-volatile memory 11, provide the storage required for real-time and historical data, while the front panel interface 112 allows users to interact with the system and monitor meter status. The communication interface 114 ensures connectivity with external devices, supporting data transmission for further analysis or remote monitoring.

In this setup, the controller integrates these hardware elements to perform the critical tasks of measuring, calculating, and analyzing voltage data, automating the identification of the electricity meter's wiring configuration and voltage rating without manual intervention.

The method begins with Step 202, where the controller measures a plurality of voltage values, including the phase voltages (V_{A}, V_{B}, V_{C}) relative to a virtual neutral point and line voltages (V_{AB}, V_{BC}, V_{CA}). These voltage values are sensed by the meter's sensors, digitized by analog-to-digital converters, and fed into the controller for further analysis.

A virtual neutral point is a reference point that is mathematically calculated rather than being physically present in the system. It is typically generated in systems where the neutral point may not be directly accessible or where a three-phase configuration lacks a neutral line, such as in a three-phase three-wire configuration. In these cases, the virtual neutral point is used as a reference for calculating phase voltages.

The meter first measures the line voltages (V_{AB}, V_{BC}, V_{CA}), which are the voltages between phases. These line voltages can be directly measured without the need for a neutral point reference. Simultaneously, the meter also measures the voltage of each phase relative to ground (typically the ground reference of the meter), denoted as V_{AG}, V_{BG}, and V_{CG}.

Assuming an ideal balanced three-phase system, the sum of the three-phase voltages is zero:

$${V}_{A} + {V}_{B} + {V}_{C} = 0$$

Each phase voltage can be decomposed into two components: the voltage relative to the neutral point and the voltage of the neutral point relative to ground.

$${V}_{AG} = {V}_{A} + {V}_{NG}$$

$${V}_{BG} = {V}_{B} + {V}_{NG}$$

$${V}_{CG} = {V}_{C} + {V}_{NG}$$

V_{AG}, V_{BG}, and V_{CG} are the phase voltages relative to ground. These are the actual voltages measured by the sensors in the system with respect to the ground reference. V_{A}, V_{B} and V_{C} are the phase voltages relative to the neutral point. These are the voltages measured between each phase and the neutral point. V_{NG} is the voltage of the neutral point (or virtual neutral point) relative to ground.

According to formular 1-4, the virtual neutral point voltage relative to ground (V_{NG}) can be calculated as:

$${V}_{NG} = \frac{{V}_{AG} + {V}_{BG} + {V}_{CG}}{3}$$

Once the voltage of the virtual neutral point is known, the phase voltages relative to the virtual neutral point can be calculated as follows:

$${V}_{A} = {V}_{AG} - {V}_{NG}$$

$${V}_{B} = {V}_{BG} - {V}_{NG}$$

$${V}_{C} = {V}_{CG} - {V}_{NG}$$

This method allows the electricity meter to effectively simulate the existence of a neutral point, which is crucial for calculating phase voltages in systems without a physical neutral line, such as in three-phase three-wire configurations. By deriving the virtual neutral point through these measurements and calculations, the controller can perform further analysis on the phase voltages relative to the virtual neutral point, enabling accurate wiring configuration identification and voltage analysis.

In addition to measuring the phase voltages, the controller also captures the line voltages (V_{AB}, V_{BC}, V_{CA}). These values represent the voltage difference between the phases and are directly measured by the sensors attached to the power lines. The line voltages are important for performing further analyses, such as determining the system's wiring configuration.

Once the phase voltages relative to the virtual neutral point and the line voltages are measured and digitized, they are fed into the controller for further analysis. This includes calculations of effective values, phase angles, and other parameters, as described in subsequent steps of the method. The conversion of these voltage measurements into digital data by the A/D converters ensures that the controller can accurately process and analyze the values, leading to the identification of the wiring configuration and voltage rating of the electricity meter.

Thus, by leveraging the sensors, A/D converters, and the computational capabilities of the controller, the system is able to measure voltage values with respect to a virtual neutral point, enabling the automation of voltage analysis and wiring configuration identification in a robust and accurate manner.

In Step 204, the controller calculates effective values, such as root-mean-square (RMS) values, and phase angles for each of the measured voltage values. These calculations help to normalize the voltage data and prepare it for further processing.

In Step 204, the controller begins by analyzing the digitized voltage data that was captured from the sensors 102 and converted by the analog-to-digital converters (A/D converters 104) in FIG. 1. The objective of this step is to compute the effective values (such as RMS) and the phase angles for each of the measured voltage values, which includes phase voltages (V_{A}, V_{B}, V_{C}) and line voltages (V_{AB}, V_{BC}, V_{CA}).

The root-mean-square (RMS) value is a crucial parameter for analyzing alternating current (AC) voltage and is used to quantify the effective power of an AC waveform. The RMS value represents the equivalent DC voltage that would produce the same power as the AC waveform over one complete cycle. For a sinusoidal waveform, the RMS value is given by the following equation:

$${V}_{RMS} = \sqrt{\frac{1}{T} {\int }_{0}^{T} {V ( t )}^{2} dt}$$

Where V(t) is the instantaneous voltage at time t, T is the period of the waveform.

In a practical implementation, since the voltage data is already digitized by the A/D converters, the controller approximates the RMS value by summing and averaging the squared voltage samples over a discrete number of time intervals. Specifically, the controller processes the voltage data sampled at regular intervals and computes the RMS value using the following formula for N samples:

$${V}_{RMS} = \sqrt{\frac{1}{N} {\sum }_{i = 1}^{N} {{V}_{i}}^{2}}$$

Where Vᵢ is the measured voltage at sample point i, N is the total number of samples in one cycle.

The controller performs this calculation for each of the measured voltage values, including the phase voltages (V_{A}, V_{B}, V_{C}) and the line voltages (V_{AB}, V_{BC}, V_{CA}). This ensures that the controller can accurately represent the effective voltage values for further analysis.

The phase angle between voltages is critical for understanding the relationships between the different phases in a three-phase system. The phase angle indicates the time shift between two sinusoidal waveforns and is essential for determining whether the system is balanced and for identifying the wiring configuration.

To calculate the phase angle between two voltages, the controller uses the time-domain data provided by the sensors and the A/D converters. For two sinusoidal waveforms, the phase angle θ can be calculated by measuring the time difference Δt between their zero-crossing points and converting this time difference into an angular displacement using the system frequency f (typically 50 Hz or 60 Hz):

$$θ = 360 ° \times f \times Δ t$$

Where f is the frequency of the system (e.g., 50 Hz or 60 Hz), Δt is the time difference between the zero-crossings of the two voltages.

Alternatively, if the controller uses the digitized voltage samples to represent the two sinusoidal waveforms, the phase angle can be calculated using the dot product formula in the frequency domain. The phase angle θ between two sampled voltage waveforms V_{A} and V_{B} can be computed as:

$$cos θ = \frac{\sum {V}_{A} [ i ] \cdot {V}_{B} [ i ]}{\sqrt{\sum {{V}_{A} [ i ]}^{2}} \cdot \sqrt{\sum {{V}_{B} [ i ]}^{2}}}$$

From the dot product result, the controller calculates the phase angle θ using the inverse cosine (arccos) function.

The controller performs this phase angle calculation for:
The phase voltages relative to each other (e.g., V_{A} to V_{B}, V_{B} to V_{C}, etc.),
The line voltages relative to each other (e.g., V_{AB} to V_{BC}, V_{BC} to V_{CA}, etc.).

The calculated RMS values and phase angles are important for normalizing the voltage data. By converting the instantaneous voltage readings into RMS values, the controller ensures that the voltage measurements are in a standardized form, allowing for easier comparison between different phases and line voltages. The phase angle calculations are essential for determining whether the system is balanced, as any significant deviation from the expected 120-degree separation between phases indicates an imbalance.

In Step 204, the controller calculates RMS values and phase angles for each of the measured voltage values. These calculations normalize the voltage data and provide essential parameters for further analysis, enabling the controller to accurately assess the electrical characteristics of the system and determine the wiring configuration in subsequent steps.

In Step 206, the controller performs a multidimensional analysis on the measured and calculated voltage values to extract key electrical parameters that help determine the wiring configuration and system characteristics. This multidimensional analysis involves several distinct calculations, which work together to provide a comprehensive understanding of the electrical system.

One of the first tasks in this analysis is voltage ratio analysis. The controller calculates two important ratios to assess the balance and stability of the system. The first ratio is calculated as the maximum value of the phase voltages (V_{A}, V_{B}, V_{C}) divided by the minimum value of the phase voltages. This ratio gives the controller insight into any imbalances between the phases, which can indicate issues with the wiring configuration or system load. The formula for the first ratio can be expressed as:

$$R 1 = \frac{max ( {V}_{A} , {V}_{B} , {V}_{C} )}{min ( {V}_{A} , {V}_{B} , {V}_{C} )}$$

The second ratio is calculated in a similar manner, but it uses the line voltages (V_{AB}, V_{BC}, V_{CA}) instead of the phase voltages. This second ratio provides additional information on the relationships between the phases. The formula for the second ratio is:

$$R 2 = \frac{max ( {V}_{AB} , {V}_{BC} , {V}_{CA} )}{min ( {V}_{AB} , {V}_{BC} , {V}_{CA} )}$$

These ratios are critical in identifying any anomalies or inconsistencies in the phase or line voltages, and they form the basis for detecting potential wiring configuration issues.

Next, the controller conducts a phase angle analysis. The purpose of this analysis is to calculate the phase angle differences between the phase voltages and the line voltages. The phase angle is the angular displacement between the sine waves representing the voltages, and it provides information about how synchronized or out-of-phase the system is.

In a typical three-phase system, multiple phase angles need to be evaluated, and all these angles must meet the defined requirements to ensure the system is functioning correctly.

Specifically, for the phase voltages (V_{A}, V_{B}, V_{C}), there are three distinct phase angle differences to consider:
The phase angle difference between V_{A} and V_{B},
The phase angle difference between V_{B} and V_{C},
The phase angle difference between V_{C} and V_{A}.

Each of these pairs of phase voltages should have a phase angle difference close to 120 degrees, accounting for minor variations due to system imbalances or load conditions. The controller calculates these angular differences by analyzing the time-domain data from the digitized voltage signals. For each pair, the controller determines the time difference between the zero-crossings of the sine waves and converts this into an angular phase difference based on the system's frequency (typically 50 Hz or 60 Hz).

Similarly, the phase angle differences between the line voltages (V_{AB}, V_{BC}, V_{CA}) must also be calculated. Line voltages represent the potential difference between pairs of phase conductors, and their angular displacement in a balanced system should ideally be 60 degrees. The controller performs the same process of identifying the zero-crossings and calculating the phase angle differences for the following pairs:
The phase angle difference between V_{AB} and V_{BC},
The phase angle difference between V_{BC} and V_{CA},
The phase angle difference between V_{CA} and V_{AB}.

By comparing both the phase voltage and line voltage phase angles to their respective expected values (120 degrees for phase voltages and 60 degrees for line voltages), the controller can assess whether the system is balanced or detect any significant deviations. If the phase angles deviate beyond predefined tolerances, it may indicate issues such as incorrect wiring, load imbalances, or other system faults. These deviations would trigger further analysis or alerts, helping to ensure the system's proper functioning and integrity.

The third part of the multidimensional analysis is the zero-sequence voltage analysis, which is used to detect imbalances in the three-phase system. The controller calculates the zero-sequence voltage (V₀) as the average of the three phase voltages (V₄, V_{B}, V_{C}). The zero-sequence voltage is a measure of the system's balance; in an ideal, perfectly balanced system, the sum of the three phase voltages should be zero, and the zero-sequence voltage will also be zero. The formula for calculating the zero-sequence voltage is:

$${V}_{0} = \frac{{V}_{A} + {V}_{B} + {V}_{C}}{3}$$

If the zero-sequence voltage is significantly different from zero, it indicates that there is an imbalance in the system, which may be due to issues such as incorrect wiring, unequal load distribution, or phase voltage discrepancies. The controller compares the calculated zero-sequence voltage to a predefined threshold to determine if the system is operating within acceptable parameters.

By performing these three types of analyses—voltage ratio analysis, phase angle analysis, and zero-sequence voltage analysis—the controller gathers a comprehensive set of data that can be used to assess the overall health of the electrical system. This multidimensional approach allows the controller to accurately identify any wiring configuration issues, detect imbalances, and ensure that the system is operating as expected. These calculations are then used as inputs for subsequent steps in the method, where the controller makes final determinations about the wiring configuration and voltage rating of the electricity meter, Through this integrated approach, the multidimensional analysis serves as the foundation for accurate and reliable system identification.

In Step 208, the controller determines the wiring configuration of the electricity meter based on the results of the multidimensional analysis. For instance, a three-phase three-wire configuration is identified when the absolute value of the calculated zero-sequence voltage is less than a first threshold, and the first and second ratios, as well as the phase angle differences, fall within specified ranges. Conversely, a three-phase four-wire configuration is identified when the absolute value of the zero-sequence voltage exceeds a second threshold and the other calculated parameters fall within different ranges.

In Step 208, the controller uses the results obtained from the multidimensional analysis to determine the wiring configuration of the electricity meter. This step is critical because the wiring configuration directly impacts how the electricity meter interprets voltage and current data for accurate energy measurements. The controller evaluates the phase voltage data, line voltage data, voltage ratios, phase angle differences, and the zero-sequence voltage, all of which were calculated in the previous steps, to make this determination.

The process begins by analyzing the absolute value of the zero-sequence voltage (V₀), which provides a key indication of the system's balance. In a balanced three-phase system, the zero-sequence voltage should ideally be zero, meaning the sum of the phase voltages cancels out. However, deviations from zero occur in unbalanced systems or configurations with a neutral connection. To account for this, the controller compares the calculated zero-sequence voltage against predefined thresholds. If the absolute value of the zero-sequence voltage is less than a first threshold, it suggests that the system is closely balanced and likely to be operating in a three-phase three-wire configuration. This is because, in a three-wire system, there is no neutral line, and the voltages tend to balance more symmetrically across the phases.

Once the controller identifies that the zero-sequence voltage falls below the first threshold, it proceeds to verify this finding by analyzing the voltage ratios and phase angle differences. The controller checks whether the first ratio (the ratio of the maximum phase voltage to the minimum phase voltage) and the second ratio (the ratio of the maximum line voltage to the minimum line voltage) both fall within specified ranges. For a three-phase three-wire configuration, these ratios typically hover around values close to unity because the phase voltages and line voltages should be relatively balanced. The controller also verifies that the phase angle differences between the phase voltages and line voltages fall within expected ranges—typically around 120 degrees between phase voltages in an ideal three-phase system. If all these parameters conform to the predefined ranges, the controller conclusively identifies the system as a three-phase three-wire configuration.

Conversely, if the absolute value of the calculated zero-sequence voltage exceeds a second threshold, this indicates a greater imbalance in the system, suggesting the presence of a neutral line, as is the case in a three-phase four-wire configuration. In such systems, the neutral line allows for unequal load distribution across the phases, which often results in a higher zero-sequence voltage. The controller evaluates this higher zero-sequence voltage and checks whether it exceeds the second threshold, confining that the system is a four-wire configuration.

Similar to the analysis for a three-wire configuration, the controller also examines the first and second ratios and the phase angle differences for the four-wire system. However, the acceptable ranges for these parameters will differ from those in the three-wire system. For instance, the phase voltages relative to the neutral line may show more significant variation, leading to a slightly larger voltage ratio range. Additionally, the phase angle differences may deviate slightly from the ideal 120-degree separation. If the zero-sequence voltage exceeds the second threshold, and the first and second ratios and phase angles fall within the ranges defined for a four-wire system, the controller identifies the system as a three-phase four-wire configuration.

Through this process, the controller ensures that it accurately determines whether the electricity meter is connected to a three-wire or four-wire system. By using thresholds for the zero-sequence voltage, coupled with analysis of voltage ratios and phase angle differences, the controller can reliably distinguish between these two common wiring configurations, ensuring the meter is correctly configured for accurate energy measurement and system monitoring. This automated identification method reduces the risk of human error and improves the overall reliability of the electricity metering system.

In some embodiments, determining the wiring configuration comprises identifying a three-phase three-wire configuration when the absolute value of the calculated zero-sequence voltage is less than a first threshold (e.g., 1 volt), which is predefined to account for near-perfect system balance. The first ratio (the ratio of the maximum to minimum phase voltages) must fall between 1.00 and 1.10, and the second ratio (the ratio of the maximum to minimum line voltages) must be within 0.95 and 1.10. Additionally, any phase angle difference between the phase voltages should fall within 1150 to 125°, while any phase angle difference between the line voltages should be between 55° and 65°.

Conversely, a three-phase four-wire configuration is identified when the absolute value of the zero-sequence voltage exceeds a second threshold (e.g., 2 volts), indicative of the presence of a neutral line. In this case, the first ratio should be between 1.00 and 1.15, and the second ratio should be within 0.95 and 1.15. Any phase angle difference between the phase voltages must be between 110′ and 130°, and any phase angle difference between the line voltages should be within 50° and 70°.

Step 210 involves performing a voltage spectrum analysis to determine the voltage rating of the meter. The controller performs a Fast Fourier Transform (FFT) on the measured voltage values to obtain the fundamental frequency amplitudes, enabling the controller to calculate the voltage rating of the system. In some embodiments, the method includes additional steps where the controller collects voltage data over a predetermined period and calculates statistical parameters, such as the mean, standard deviation, and 95% confidence interval for the fundamental frequency amplitudes. The voltage rating is then determined by comparing these statistical parameters to predefined voltage rating ranges.

In Step 210, the controller carries out a voltage spectrum analysis to determine the voltage rating of the electricity meter. This analysis is essential for understanding the characteristics of the electrical system and ensuring that the meter is properly configured to measure the correct voltage level. To perform this analysis, the controller utilizes a mathematical technique known as the Fast Fourier Transform (FFT), which is well-suited for analyzing periodic signals like those found in alternating current (AC) systems. The FFT converts the time-domain voltage measurements into the frequency domain, allowing the controller to identify the amplitudes of various frequency components present in the measured voltage waveforns.

The controller begins by processing the digitized voltage values, which were obtained from the sensors in previous steps. These values represent the instantaneous voltage levels over time for the phase and line voltages. The FFT algorithm is then applied to this time-domain data, which breaks the signal down into its constituent frequency components. The most important of these components for determining the voltage rating is the fundamental frequency, which corresponds to the base frequency of the AC system (typically 50 Hz or 60 Hz, depending on the region). The FFT outputs the amplitude of the fundamental frequency, along with amplitudes of any harmonic frequencies that may be present in the system.

Once the controller has the fundamental frequency amplitude, it can begin calculating the voltage rating of the system. The fundamental frequency amplitude represents the primary voltage level of the system, and this value is critical for determining whether the system falls within expected voltage ranges, such as low voltage, medium voltage, or high voltage. The controller compares the amplitude of the fundamental frequency against predefined voltage rating thresholds stored in the system's memory. These thresholds correspond to different voltage classifications, allowing the controller to assign a specific voltage rating to the meter based on the measured values.

In some embodiments, the method goes beyond a single measurement and includes additional steps where the controller collects voltage data over a predetermined period. By sampling voltage values over time, the controller is able to build a more robust dataset that accounts for fluctuations and variations in the system. Once a sufficient amount of data has been collected, the controller calculates several statistical parameters to enhance the accuracy of the voltage rating determination. These parameters may include the mean value of the fundamental frequency amplitudes, which provides an average voltage level over the measurement period; the standard deviation, which measures the variability in the voltage levels; and a 95% confidence interval, which indicates the range within which the true voltage value is likely to fall with high certainty.

These statistical calculations are crucial in systems where voltage levels may fluctuate due to varying loads or external factors. By averaging the data and calculating the spread of the voltage levels, the controller can more accurately determine the voltage rating, even in the presence of minor variations. The use of a confidence interval also helps ensure that the meter's voltage rating is based on a reliable dataset, reducing the likelihood of erroneous readings due to short-term anomalies.

After calculating the necessary statistical parameters, the controller compares the results to predefined voltage rating ranges. These ranges are stored in the system's memory and correspond to different classes of electrical systems, such as 230V for residential systems or 400V for industrial systems. If the mean amplitude of the fundamental frequency falls within one of these ranges, the controller assigns the corresponding voltage rating to the meter. This process ensures that the meter is correctly calibrated to measure the appropriate voltage for the specific electrical system it is connected to.

By performing the voltage spectrum analysis and using statistical methods to refine the results, the controller is able to determine the voltage rating with a high degree of accuracy. This step is crucial for ensuring that the meter operates correctly in diverse electrical environments and can adapt to different voltage levels without requiring manual reconfiguration. Through the use of FFT, statistical analysis, and predefined voltage rating thresholds, the system provides an automated and reliable method for determining the voltage rating of the meter.

After the initial identification of the wiring configuration and voltage rating, the process includes confirming the results by repeating the identification steps over multiple iterations. This iterative approach ensures the reliability and accuracy of the system's conclusions. During each iteration, the controller performs the same set of steps, including measuring voltage values, calculating effective values, conducting multidimensional analysis, and determining the wiring configuration and voltage rating. By repeating these steps multiple times, the system can identify patterns and confirm consistency in the results.

To further refine the confirmation process, the identification procedure is conducted for a predetermined number of iterations, typically based on system requirements and conditions, Once the specified number of iterations is complete, the controller checks for consistency across the results. If the wiring configuration and voltage rating remain consistent across all iterations, the results are confirmed, ensuring a high degree of confidence in the identification. However, if discrepancies are detected in any iteration, an uncertainty is reported. This may signal instability in the system or potential external factors affecting the measurement, such as fluctuating loads or electrical disturbances. The system then generates a report on the inconsistency, allowing operators or technicians to investigate further or adjust the system parameters accordingly.

Additionally, the system can adapt the threshold values used in the multidimensional analysis over time. The initial threshold values—used for determining voltage ratios, phase angles, and zero-sequence voltage levels—are often based on predefined system specifications or standards. However, in practice, electrical systems can vary depending on the grid environment, load characteristics, or other local conditions. To improve adaptability, the system uses historical data from past measurements to refine these threshold values. By analyzing trends and performance metrics from previous data, the system adjusts the thresholds dynamically, making the identification process more accurate for the specific electrical grid environment it monitors. This adaptability is crucial for ensuring the system remains effective across different grid conditions, particularly in environments where there may be fluctuations or non-ideal operating conditions.

Beyond identification, the system is also designed to detect anomalies in the measured voltage values. Anomalies—such as voltage sags, surges, or transient events—can significantly impact the accuracy of the system and may indicate potential faults or external disturbances. The controller continuously monitors the measured voltage values for any irregularities, comparing them against expected norms or patterns. When an anomaly is detected, the system immediately generates an alert to notify the relevant parties. This alert system allows operators to take swift corrective action, preventing potential damage to the system or connected equipment. For example, if a voltage surge is detected, the system might trigger an immediate warning, allowing technicians to respond and prevent further disruptions. The anomaly detection capability ensures ongoing reliability and safety by monitoring real-time conditions and signaling when intervention may be necessary.

Overall, these processes work together to confirm the wiring configuration and voltage rating while also making the system more adaptable to real-world variations and responsive to potential problems. Through repeated iterations, adaptive thresholding, and real-time anomaly detection, the system offers a robust and accurate method for monitoring and managing electrical systems in diverse operating environments.

Embodiments of the teachings of the present disclosure have been described in an illustrative manner. It is to be understood that the terminology that has been used, is intended to be in the nature of words of description rather than of limitation. Many modifications and variations of the embodiments are possible in light of the above teachings. Therefore, within the scope of the appended claims, the embodiments can be practiced other than specifically described.

What is claimed is:

1. A method for identifying a wiring configuration of an electricity meter, the method comprising:
measuring, by a controller of the electricity meter, a plurality of voltage values including phase voltages (V_{A}, V_{B}, V_{C}) relative to a virtual neutral point and line voltages (V_{AB}, V_{BC}, V_{CA});
calculating, by the controller, effective values and phase angles for the measured voltage values;
performing, by the controller, a multidimensional analysis including a voltage ratio analysis, a phase angle analysis, and a zero-sequence voltage analysis;
determining, based on the multidimensional analysis, the wiring configuration of the electricity meter;
performing, by the controller, a voltage spectrum analysis to determine a voltage rating of the electricity meter.

2. The method of claim 1, wherein the voltage ratio analysis comprises:
calculating a first ratio as a maximum of the phase voltages divided by a minimum of the phase voltages; and
calculating a second ratio as a maximum of the line voltages divided by a minimum of the line voltages.

3. The method of claim 2, wherein the phase angle analysis comprises:
calculating phase angle differences between the phase voltages; and
calculating phase angle differences between the line voltages.

4. The method of claim 3, wherein the zero-sequence voltage analysis comprises:
calculating a zero-sequence voltage as an average of the phase voltages.

5. The method of claim 4, wherein determining the wiring configuration comprises:
identifying a three-phase three-wire configuration when an absolute value of the calculated zero-sequence voltage is less than a first threshold, the calculated first ratio is between 1.00 and 1.10, the calculated second ratio is between 0.95 and 1.10, any calculated phase angle difference between the phase voltages is between 115° and 125°, and any calculated phase angle difference between the line voltages is between 55° and 65°;
identifying a three-phase four-wire configuration when the absolute value of the calculated zero-sequence voltage exceeds a second threshold, the calculated first ratio is between 1.00 and 1.15, the calculated second ratio is between 0.95 and 1.15, any calculated phase angle difference between the phase voltages is between 110° and 130°; and any calculated phase angle difference between the line voltages is between 50° and 70°.

6. The method of claim 1, wherein the voltage spectrum analysis comprises:
performing a Fast Fourier Transform (FFT) on the measured voltage values to obtain fundamental frequency amplitudes.

7. The method of claim 6, further comprising:
collecting voltage data over a predetermined time period;
calculating statistical parameters including a mean, a standard deviation, and a 95% confidence interval for the fundamental frequency amplitudes; and
determining the voltage rating by comparing the statistical parameters to predefined voltage rating ranges.

8. The method of claim 1, further comprising: confirming the determined wiring configuration and voltage rating through multiple iterations of the identification process.

9. The method of claim 8, wherein confirming the determined wiring configuration and voltage rating comprises:
performing the identification process for a predetermined number of iterations; confirming the results if consistent across the iterations; and
reporting an uncertainty if the results are inconsistent across the iterations.

10. The method of claim 1, further comprising:
adapting threshold values used in the multidimensional analysis based on historical data to improve adaptability to different power grid environments.

11. The method of claim 1, further comprising:
detecting anomalies in the measured voltage values; and
generating an alert when an anomaly is detected.

12. A system for identifying a type of an electricity meter, the system comprising:
a voltage measurement unit configured to measure a plurality of voltage values;
a processor; and
a memory storing instructions that, when executed by the processor, cause the system to perform the method of claim 1.

13. A non-transitory computer-readable storage medium storing instructions that, when executed by a processor of an electricity meter, cause the processor to perform the method of claim 1.
